(19) United States
(12) Patent Application Publication
(10) Pub. No.: US 2024/0250145 A1
(43) Pub. Date: Jul. 25, 2024

(54) FERROELECTRIC FILM, MANUFACTURING METHOD THEREFOR, AND ELECTRONIC COMPONENT

(71) Applicants: Murata Manufacturing Co., Ltd., Nagaokakyo-shi (JP); JAPAN ADVANCED INSTITUTE OF SCIENCE AND TECHNOLOGY, Nomi-shi (JP)

(72) Inventors: Shingo YONEDA, Nagaokakyo-shi (JP); Takaaki MIYASAKO, Nagaokakyo-shi (JP); Tadasu HOSOKURA, Nagaokakyo-shi (JP); Eisuke TOKUMITSU, Nomi-shi (JP)

(21) Appl. No.: 18/584,171

(22) Filed: Feb. 22, 2024

Related U.S. Application Data
(63) Continuation of application No. PCT/JP2022/034579, filed on Sep. 15, 2022.

(30) Foreign Application Priority Data
Sep. 17, 2021 (JP) 2021-152238

(51) Int. Cl. H01L 29/51; H01L 29/78

(52) U.S. Cl. CPC H01L 29/516; H01L 28/60; H01L 29/78391

(57) ABSTRACT

A ferroelectric film that includes: hafnium oxide having a fluorite structure; a metal oxide having one or more elements selected from La, Ce and Bi; and less than 5 mol % of carbon, wherein the ferroelectric film is a polycrystalline body having an average particle size of less than 10 nm.

### CROSS REFERENCE TO RELATED APPLICATIONS

The present application is a continuation of International application No. PCT/JP2022/034579, filed Sep. 15, 2022, which claims priority to Japanese Patent Application No. 2021-152238, filed Sep. 17, 2021, the entire contents of each of which are incorporated herein by reference.

### TECHNICAL FIELD

The present disclosure relates to a ferroelectric film, a manufacturing method therefor, and an electronic component.

### BACKGROUND ART

A ferroelectric field-effect transistor (Fe-FET) including a ferroelectric used as a gate insulating film is applied to, for example, a memory element of an integrated circuit (IC) card. It is generally known that a ferroelectric has such a property that ferroelectricity becomes weaker as the ferroelectric becomes smaller and thinner. Therefore, when a ferroelectric field-effect transistor is applied to a memory element, the above-mentioned property makes it difficult to make the memory element smaller and more highly-integrated.

In recent years, it has been reported that a thin film of hafnium oxide (HfO₂) exhibits ferroelectricity, and various research and development on the thin film of hafnium oxide have been conducted. Specifically, PTL 1 discloses a capacitor including a thin film of hafnium oxide. Furthermore, NPL 1 reports that a ferroelectric applicable to a ferroelectric field-effect transistor was obtained by heat-treating a thin film of hafnium oxide in vacuum.

PTL 1: International Publication No. WO 2019/208340

NPL 1: Mohit, et al. “Indium oxide and indium-tin-oxide channel ferroelectric gate thin film transistors with yttrium doped hafnium-zirconium dioxide gate insulator prepared by chemical solution process”, Japanese Journal of Applied Physics, Japan, 15 January 2021. Volume 60, Number SBBM02.

### SUMMARY OF THE INVENTION

However, when a thin film of hafnium oxide is used in an electronic component such as a ferroelectric field-effect transistor, the thin film of hafnium oxide needs to exhibit ferroelectricity and have a high insulating property. For example, when a thin film of hafnium oxide is used as a gate insulating film of a ferroelectric field-effect transistor, the highly reliable transistor operation cannot be obtained if a leakage current occurs in the thin film of hafnium oxide.

Accordingly, an object of the present disclosure is to provide a ferroelectric film exhibiting ferroelectricity and having a high insulating property, a manufacturing method for the ferroelectric film, and an electronic component.

A ferroelectric film according to an aspect of the present disclosure includes: hafnium oxide having a fluorite structure; a metal oxide having one or more elements selected from La, Ce and Bi; and less than 5 mol % of carbon.

An electronic component according to an aspect of the present disclosure includes: the above-described ferroelectric film; and an electrode on a surface of the ferroelectric film.

A manufacturing method according to an aspect of the present disclosure includes: preparing a deposition target; preparing a chemical solution serving as a raw material of a ferroelectric film; spin-coating the chemical solution on the deposition target; and by heat treatment under oxygen atmosphere, precipitating hafnium oxide having a fluorite structure from the chemical solution spin-coated on the deposition target. The chemical solution includes, as raw material salts, a metal alkoxide salt having Hf, and a metal alkoxide salt having one or more elements selected from La, Ce and Bi.

According to an aspect of the present disclosure, a ferroelectric film exhibiting ferroelectricity and having high insulating property can be obtained by setting an amount of carbon contained in the ferroelectric film to be less than 5 mol %.

### BRIEF DESCRIPTION OF THE DRAWINGS

FIG. 1 is an X-ray diffraction spectrum of a ferroelectric film according to an embodiment.

FIG. 2 is a polarization-electric field curve of the ferroelectric film according to the embodiment.

FIG. 3 is a leakage current-electric field curve of the ferroelectric film according to the embodiment.

FIG. 4 is a polarization-electric field curve of a ferroelectric film for comparison.

FIG. 5 shows a capacitor including the ferroelectric film according to the embodiment.

FIG. 6 shows a transistor including the ferroelectric film according to the embodiment.

FIG. 7 shows an electrical property of the transistor including the ferroelectric film according to the embodiment.

### DETAILED DESCRIPTION OF THE PREFERRED EMBODIMENTS

### Embodiment

A ferroelectric film according to the present embodiment, a manufacturing method therefor, and an electronic component will be described in detail below with reference to the drawings, in which the same or corresponding portions are denoted by the same reference characters and description thereof will not be repeated.

### [Ferroelectric Film]

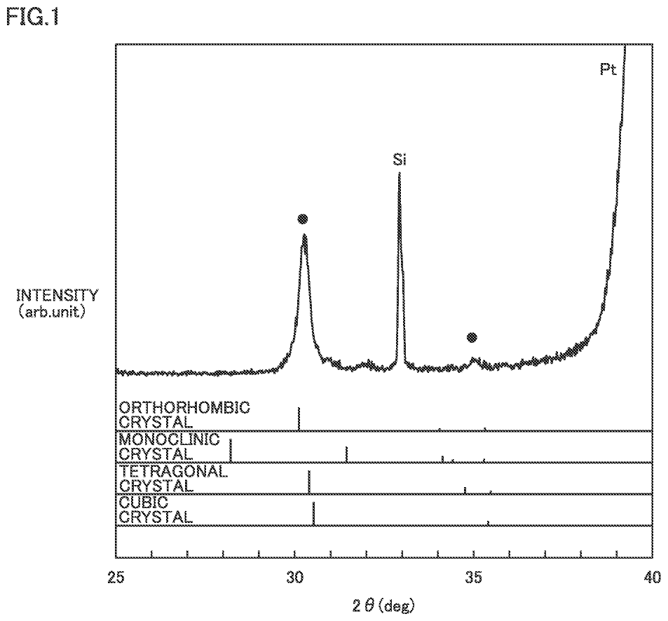

A ferroelectric film according to an embodiment will be first described. The ferroelectric film is a thin film of hafnium oxide (HfO₂) and hafnium oxide has a fluorite structure such that the ferroelectric film exhibits ferroelectricity. FIG. 1 is an X-ray diffraction spectrum of the ferroelectric film according to the embodiment. In FIG. 1, the horizontal axis indicates an angle, and the vertical axis indicates an intensity. Since the diffraction lines appearing in the vicinity of 30° and 35° shown in FIG. 1 can be attributable to a cubic fluorite structure, a tetragonal fluorite structure or an orthorhombic fluorite structure, it can be seen that the ferroelectric film according to the present embodiment includes hafnium oxide having a fluorite structure.

Since a pure HfO₂ film does not exhibit ferroelectricity, the film needs to include an element-replaced metal oxide. Particularly, a metal oxide replaced with an ion larger than a hafnium ion (Hf⁴⁺) is desirable, and it is effective to include a metal oxide replaced with an element such as La, Ce or Bi. The ferroelectric film according to the present embodiment includes a metal oxide having one or more types of elements selected from La, Ce and Bi. It can be confirmed from the X-ray diffraction spectrum shown in FIG. 1 that an HfO₂ film replaced with Ce and having a fluorite structure is formed. A contained amount of the metal oxide replaced with an element such as La, Ce or Bi is preferably 1 mol % to 15 mol %.

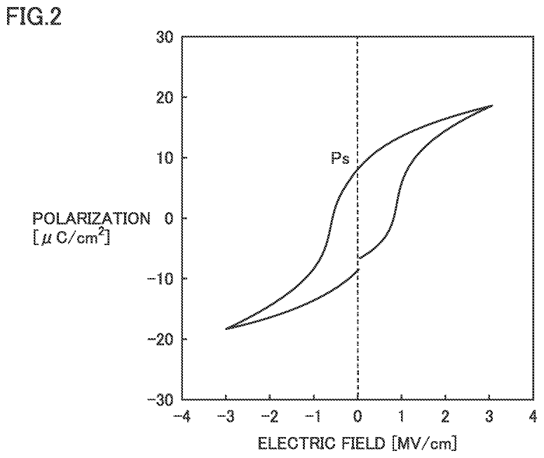

An electric field property of polarization of the ferroelectric film according to the present embodiment will be described. FIG. 2 is a polarization-electric field curve of the ferroelectric film according to the embodiment. In FIG. 2, the horizontal axis indicates an electric field, and the vertical axis indicates polarization. Generally, when a polarization-electric field curve changes such that a history of polarization is generated with respect to an electric field, it can be determined that an insulating film has ferroelectricity. Specifically, in FIG. 2, polarization (residual polarization) when changing the electric field from 0 MV/cm to approximately 3 MV/cm and then changing the electric field to 0 MV/cm again corresponds to spontaneous polarization Ps and polarization of about 10 μC/cm² is present in the film. That is, it can be seen from FIG. 2 that the ferroelectric film according to the present embodiment has ferroelectricity.

Furthermore, in the ferroelectric film according to the present embodiment, a leakage current can be reduced by setting an amount of carbon contained in the ferroelectric film to be less than 5 mol %. It has been uncertain so far why the leakage current of the ferroelectric film increases. However, in the present disclosure, by newly focusing on the amount of carbon contained in the ferroelectric film, it has been found out that the amount of carbon contained in the ferroelectric film affects the leakage current of the ferroelectric film. That is, in the ferroelectric film according to the present embodiment, the leakage current of the ferroelectric film is suppressed to a desired amount of current or smaller by reducing the amount of carbon contained in the ferroelectric film.

The amount of carbon contained in the ferroelectric film can be measured by, for example, secondary ion mass spectrometry (SIMS). As described below, the ferroelectric film according to the present embodiment is formed by a solution method by using only metal alkoxide salts as raw material salts of a chemical solution, and is baked under oxygen atmosphere. When the amount of carbon contained in the ferroelectric film formed as described above is measured by secondary ion mass spectrometry, the amount of carbon is about 1.4 mol %, which is a small amount of carbon equal to or less than 2.0 mol %. That is, it is conceivable that in the ferroelectric film according to the present embodiment, the insulating property can be improved by the use of a raw material that makes carbon less likely to remain in the film after baking, and by baking under oxygen atmosphere for a long time. Since the ferroelectric film according to the present embodiment is formed by the solution method, the ferroelectric film according to the present embodiment is a polycrystalline body having an average particle size of less than about 10 nm.

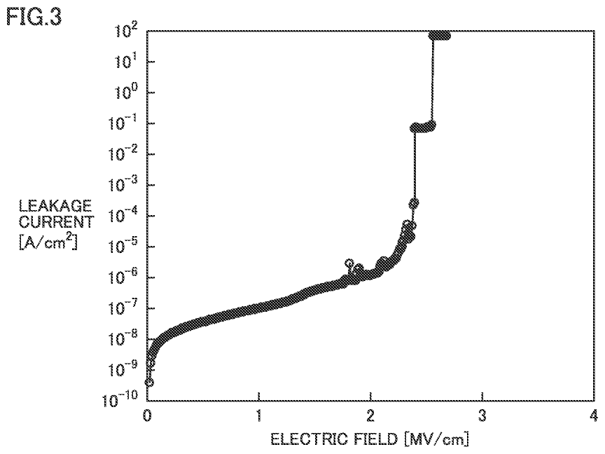

The leakage current of the ferroelectric film in which the amount of carbon contained therein is about 1.4 mol % is measured. FIG. 3 is a leakage current-electric field curve of the ferroelectric film according to the embodiment. In FIG. 3, the horizontal axis indicates an electric field, and the vertical axis indicates a leakage current. It can be seen from the leakage current-electric field curve shown in FIG. 3 that the leakage current is about 9.7×10⁻⁸ A/cm or less at the electric field of about 1 MV/cm and thus the leakage current can be significantly reduced. Therefore, the ferroelectric film according to the present embodiment has sufficient insulating property. A state in which the electric field of about 1 MV/cm is applied to the ferroelectric film corresponds to a state of a ferroelectric switch in which the direction of polarization of the ferroelectric film is switched as shown in FIG. 2.

For the purpose of comparison, a polarization-electric field curve and a leakage current of a ferroelectric film (for comparison) are measured. The ferroelectric film (for comparison) is formed by the solution method by using metal acetylacetonate salts as raw material salts of a chemical solution, and is baked in vacuum. Specifically, hafnium acetylacetonate and cerium acetylacetonate are used as the metal acetylacetonate salts, and propionic acid is used as a solvent.

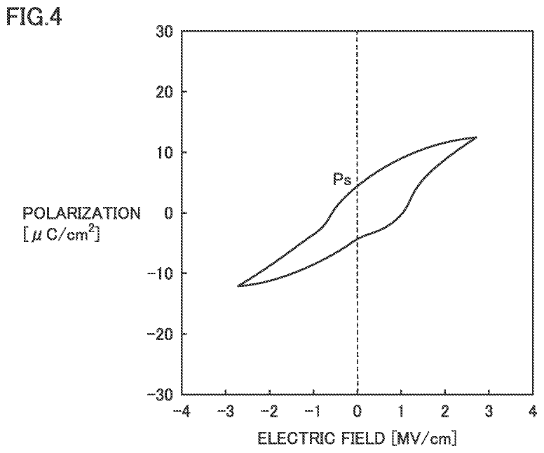

FIG. 4 is a polarization-electric field curve of the ferroelectric film for comparison. In FIG. 4, the horizontal axis indicates an electric field, and the vertical axis indicates polarization. As shown in FIG. 4, in the ferroelectric film for comparison, spontaneous polarization Ps exhibits the value of about 4 μC/cm² at the electric field of 0 MV/cm. However, due to dielectric breakdown, the electric field of 3 MV/cm cannot be applied to the ferroelectric film for comparison. Furthermore, the polarization-electric field curve of the ferroelectric film for comparison is a slightly rounded curve.

In contrast, as shown in FIG. 2, in the ferroelectric film according to the present embodiment, spontaneous polarization Ps exhibits the value of about 10 C/cm² at the electric field of 0 MV/cm. When the electric field of 3 MV/cm is applied, the polarization value is saturated, such that polarization exhibits the value of about 20 μC/cm². Furthermore, the polarization-electric field curve of the ferroelectric film according to the present embodiment is an ideal history curve.

When the leakage current of the ferroelectric film for comparison is measured, the leakage current is about 1.0×10⁻⁶ A/cm² or more, which is much larger than that of the ferroelectric film according to the present embodiment. In addition, an amount of carbon contained in the ferroelectric film for comparison is as large as about 5.0 mol % or more, which is considered to be a cause of poor insulating property of the ferroelectric film for comparison. It can be seen from the foregoing that the leakage current of the ferroelectric film can be improved by setting the amount of carbon contained in the ferroelectric film to be at least less than about 5 mol %.

In the ferroelectric film for comparison, the metal acetylacetonate salts are used as the raw material salts of the chemical solution and the metal acetylacetonate salts are more difficult to decompose than the metal alkoxide salts. Therefore, it is conceivable that in the ferroelectric film for comparison, the raw material is not sufficiently decomposed and a large amount of carbon remains in the film, which leads to poor insulating property.

In contrast, in the ferroelectric film according to the present embodiment, the metal alkoxide salts are used as the raw material salts of the chemical solution and the metal alkoxide salts are easier to decompose even at a relatively low temperature. Therefore, it is conceivable that in the ferroelectric film according to the present embodiment, the metal alkoxide salts are decomposed at a low temperature to form a fine-grained polycrystalline body, which leads to the small amount of carbon contained in the ferroelectric film. By using the metal alkoxide salts as the raw material salts, the ferroelectric film according to the present embodiment becomes a thin film of hafnium oxide (HfO₂) having excellent ferroelectricity even when the film is baked under oxygen atmosphere.

As described above, the ferroelectric film according to the present embodiment includes: hafnium oxide having a fluorite structure; a metal oxide having one or more of elements selected from La, Ce and Bi; and less than 5 mol % of carbon. Thus, according to the present embodiment, the ferroelectric film exhibiting ferroelectricity and having high insulating property can be obtained by setting the amount of carbon contained in the ferroelectric film to be less than 5 mol %. The amount of carbon contained in the ferroelectric film is further preferably less than 2 mol %. This makes it possible to further reduce the leakage current of the ferroelectric film, and thus, the ferroelectric film having higher insulating property can be obtained.

The ferroelectric film is preferably a polycrystalline body having an average particle size of less than 10 nm. This makes it possible to obtain the ferroelectric film exhibiting stronger ferroelectricity, as compared with a thin film of hafnium oxide (HfO₂) including columnar particles that is formed by a sputtering method or an atomic layer deposition (ALD) method.

An amount of the metal oxide contained in the ferroelectric film is preferably 1 mol % to 15 mol %. This makes it possible to include an appropriate amount of the element-replaced metal oxide with respect to an HfO₂ film, and thus, the ferroelectric film exhibiting stronger ferroelectricity can be obtained.

A manufacturing method according to the present embodiment is a manufacturing method for manufacturing a ferroelectric film including hafnium oxide. The manufacturing method includes: preparing a deposition target; preparing a chemical solution serving as a raw material of the ferroelectric film; spin-coating the chemical solution on the deposition target; and by heat treatment under oxygen atmosphere, precipitating hafnium oxide having a fluorite structure from the chemical solution spin-coated on the deposition target. The chemical solution includes, as raw material salts, a metal alkoxide salt having Hf, and a metal alkoxide salt having one or more types of elements selected from La, Ce and Bi. Thus, in the manufacturing method according to the present embodiment, the ferroelectric film exhibiting ferroelectricity and having high insulating property can be manufactured.

### [Capacitor Including Ferroelectric Film]

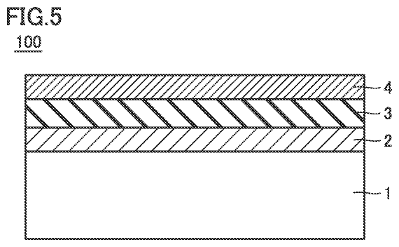

Next, a configuration of a capacitor including the ferroelectric film according to the present embodiment and a manufacturing method therefor will be described. FIG. 5 shows a capacitor 100 including the ferroelectric film according to the present embodiment. FIG. 5 shows a cross-sectional view of capacitor 100.

Capacitor 100 includes a substrate 1, a first electrode 2, a dielectric layer 3, and a second electrode 4. The material, the property, the thickness and the like of substrate 1 are arbitrarily selected. In the present embodiment, an Si(100) substrate having a thickness of 500 μm is, for example, used as substrate 1.

First electrode 2 is formed on substrate 1. The material, the property, the thickness and the like of first electrode 2 are arbitrarily selected. In the present embodiment, a Pt film having a thickness of 100 nm is, for example, used as first electrode 2.

Dielectric layer 3 is formed on first electrode 2. The ferroelectric film according to the present embodiment is used as dielectric layer 3. That is, dielectric layer 3 includes: hafnium oxide having a fluorite structure; a metal oxide having one or more elements selected from La, Ce and Bi; and less than 5 mol % of carbon. In the present embodiment, a ferroelectric film having a thickness of 60 nm is, for example, used as dielectric layer 3.

Dielectric layer 3 has ferroelectricity. Therefore, dielectric layer 3 can control a polarization state (polarization direction of spontaneous polarization) and store a signal through the application of an electric field.

Second electrode 4 is formed on dielectric layer 3. The material, the property, the thickness and the like of second electrode 4 are arbitrarily selected. In the present embodiment, a Pt film having a thickness of 100 nm is, for example, used as second electrode 4.

Capacitor 100 having the above-described structure can control the polarization state through the application of the electric filed and can be used as a storage device.

Next, a manufacturing method for capacitor 100 will be described. First, substrate 1 is prepared. Concurrently with the preparation of substrate 1, a chemical solution is prepared.

0.642 g of hafnium isopropoxide and 0.080 g of cerium isopropoxide that are metal alkoxide salts are prepared as raw material salts of the chemical solution.

In addition, 2 ml of acetic acid and 4 ml of 2-methoxyethanol are prepared as a solvent of the chemical solution.

Acetic acid and 2-methoxyethanol are put in a container and stirred. Furthermore, the raw material salts are put in the container and stirred, thereby obtaining the chemical solution.

Next, first electrode 2 made of a Pt film is formed on substrate 1 by the sputtering method.

Next, the chemical solution is coated on first electrode 2 by the spin coating method.

Specifically, in the state where a rotating table to which substrate 1 having first electrode 2 formed thereon is attached is being rotated at 3000 rotations/sec, the chemical solution is dripped onto first electrode 2 and a film of the chemical solution having a thickness of 20 nm is coated on first electrode 2 as a first coating. An amount of the chemical solution dripped is ⅓ of the prepared chemical solution. Then, substrate 1 having the film of the chemical solution formed on first electrode 2 is heated to 500° C. at a temperature rising rate of 300° C./min under oxygen atmosphere in which an oxygen flow rate is 200 ml/min, and is left for 10 minutes. As a result, a first HfO₂ film is formed on first electrode 2.

Then, the chemical solution is coated on the first HfO₂ film as a second coating by the spin coating method under the same conditions as those of the first coating, and heating is performed. As a result, a second HfO₂ film is formed. An amount of the chemical solution dripped is ⅓ of the prepared chemical solution.

Then, the chemical solution is coated on the second HfO₂ film as a third coating by the spin coating method under the same conditions as those of the first coating and the second coating, and heating is performed. As a result, a third HfO₂ film is formed. An amount of the chemical solution dripped is ⅓ of the prepared chemical solution.

As a result, dielectric layer 3 in which the first HfO₂ film, the second HfO₂ film and the third HfO₂ film all having the same thickness are stacked on first electrode 2 is formed.

Next, second electrode 4 made of a Pt film is formed on dielectric layer 3 by the sputtering method.

Next, heat treatment is performed to improve the crystallinity of dielectric layer 3 (HfO₂ films). Specifically, substrate 1 having first electrode 2, dielectric layer 3 and second electrode 4 formed thereon is heated to 800° C. at a temperature rising rate of 300° C./min under oxygen atmosphere in an oxygen flow rate of 200 ml/min, and is left for 10 minutes. Capacitor 100 is thus completed.

As described above, capacitor 100 is considered as an example of an electronic component including the ferroelectric film according to the present embodiment and an electrode formed on a surface of the ferroelectric film. Capacitor 100 includes first electrode 2 formed on one main surface of dielectric layer 3 serving as the ferroelectric film, and second electrode 4 formed on the other main surface of dielectric layer 3 serving as the ferroelectric film, and first electrode 2, dielectric layer 3 serving as the ferroelectric film, and second electrode 4 form capacitor 100. This makes it possible to implement capacitor 100 that can control the polarization state through the application of the electric field, and to use capacitor 100 as a storage device.

### [Transistor Including Ferroelectric Film]

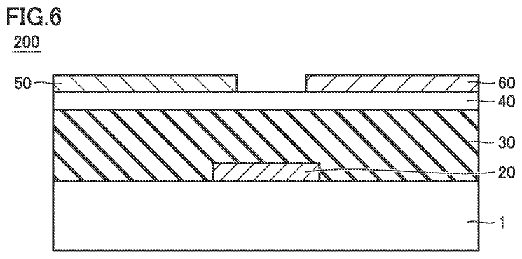

Next, a configuration of a transistor including the ferroelectric film according to the present embodiment and a manufacturing method therefor will be described. FIG. 6 shows a transistor 200 including the ferroelectric film according to the present embodiment. FIG. 6 shows a cross-sectional view of transistor 200.

Transistor 200 is a ferroelectric field-effect transistor and functions as a storage element. Transistor 200 includes substrate 1, a gate electrode 20, a gate insulating film 30, a channel forming film 40, a source electrode 50, and a drain electrode 60. The material, the property, the thickness and the like of substrate 1 are arbitrarily selected. In the present embodiment, an Si(100) substrate having a thickness of 500 μm is, for example, used as substrate 1.

Gate electrode 20 is formed on substrate 1. The material, the property, the thickness and the like of gate electrode 20 are arbitrarily selected. In the present embodiment, a Pt film having a thickness of 80 nm is, for example, used as gate electrode 20.

Gate insulating film 30 is formed on substrate 1 and gate electrode 20. The ferroelectric film according to the present embodiment is used as gate insulating film 30. That is, gate insulating film 30 includes: hafnium oxide having a fluorite structure; a metal oxide having one or more elements selected from La, Ce and Bi; and less than 5 mol % of carbon. In the present embodiment, a ferroelectric film having a thickness of 60 nm is, for example, used as gate insulating film 30.

Gate insulating film 30 has ferroelectricity. Therefore, transistor 200 in which the ferroelectric film is used as gate insulating film 30 is a ferroelectric field-effect transistor, and can control a polarization state (polarization direction of spontaneous polarization) through the application of an electric field to gate electrode 20 and can function as a storage element that stores a signal.

Channel forming film 40 is formed on gate insulating film 30. The material, the property, the thickness and the like of channel forming film 40 are arbitrarily selected. In the present embodiment, an ITO film having a thickness of 10 nm is, for example, used as channel forming film 40.

Source electrode 50 and drain electrode 60 are formed on channel forming film 40. The material, the property, the thickness and the like of each of source electrode 50 and drain electrode 60 are arbitrarily selected. In the present embodiment, a Pt film having a thickness of 80 nm is, for example, used as each of source electrode 50 and drain electrode 60. Each of source electrode 50 and drain electrode 60 is formed at a position where each of source electrode 50 and drain electrode 60 straddles gate electrode 20 when viewed in a plan view from the stacking direction of transistor 200.

Next, a manufacturing method for transistor 200 will be described. First, substrate 1 is prepared. Concurrently with the preparation of substrate 1, a chemical solution is prepared. Since a method for obtaining raw material salts of the chemical solution, a method for obtaining a solvent of the chemical solution, and a method for obtaining the chemical solution are the same as those of capacitor 100, detailed description will not be repeated.

Next, gate electrode 20 of platinum (Pt) having a film thickness of 80 nm is formed on substrate 1. Specifically, gate electrode 20 is formed by forming a photoresist having a prescribed pattern on substrate 1 using the photolithography technique, and then, forming a film of platinum (Pt) by radio-frequency (RF) sputtering and removing the photoresist by lift-off.

Next, gate insulating film 30 having a film thickness of 60 nm is formed on a surface of substrate 1 having gate electrode 20 formed thereon. Specifically, gate insulating film 30 is formed by spin-coating the prepared chemical solution on the surface of substrate 1 having gate electrode 20 formed thereon and forming a film by a chemical solution deposition (CSD) method, drying the film at 150° C., and then, baking the film at 800° C. under oxygen atmosphere to crystallize the film.

Next, channel forming film 40 having a film thickness of 10 nm is formed on gate insulating film 30. Specifically, channel forming film 40 is formed by spin-coating an ITO solution on gate insulating film 30 and forming a film by the chemical solution deposition (CSD) method, drying the film at 150° C., and then, baking the film at 500° C. under oxygen atmosphere to crystallize the film.

Next, source electrode 50 of platinum (Pt) and drain electrode 60 of platinum (Pt) each having a film thickness of 80 nm are formed on channel forming film 40. Specifically, each of source electrode 50 and drain electrode 60 is formed by forming a photoresist having a prescribed pattern on channel forming film 40 using the photolithography technique, and then, forming a film of platinum (Pt) by radio-frequency (RF) sputtering and removing the photoresist by lift-off.

Transistor 200 has such a structure that a metal-ferroelectric-semiconductor (MFS)-type gate insulating film 30 serves as the ferroelectric film. Thus, transistor 200 can function as a storage element that can store a non-volatile electric charge in gate insulating film 30 and use the stored electric charge to switch a resistance value of channel forming film 40 between a high resistance state and a low resistance state. Transistor 200 according to the present embodiment does not necessarily need to have the MFS-type structure.

Specifically, the operation when transistor 200 functions as a storage element will be described. For example, at the time of writing to transistor 200, a voltage is applied between source electrode 50 and gate electrode 20 to change the polarization direction of gate insulating film 30. The electric charge stored in gate electrode 20 functioning as a capacitor electrode of the storage element and channel forming film 40 changes in accordance with the polarization direction of gate insulating film 30. As a result, a threshold voltage changes in accordance with the change in polarization state of gate insulating film 30, and thus, a current (drain current) flowing from source electrode 50 to drain electrode 60 changes.

In transistor 200, in the case where channel forming film 40 includes, for example, an N-type semiconductor material, a change in threshold voltage in the negative direction causes an increase in drain current when a voltage (gate voltage) applied to gate electrode 20 is 0 V. In contrast, in transistor 200, a change in threshold voltage in the positive direction causes a decrease in drain current when the gate voltage is 0 V. Thus, transistor 200 can perform alternate switching between a state in which the drain current is high (on state) and a state in which the drain current is low (off state).

Therefore, transistor 200 uses the change in polarization state of gate insulating film 30 to perform alternate switching between the on state and the off state, thereby achieving storage or erasing of a signal between source and drain electrodes 50 and 60 and gate electrode 20.

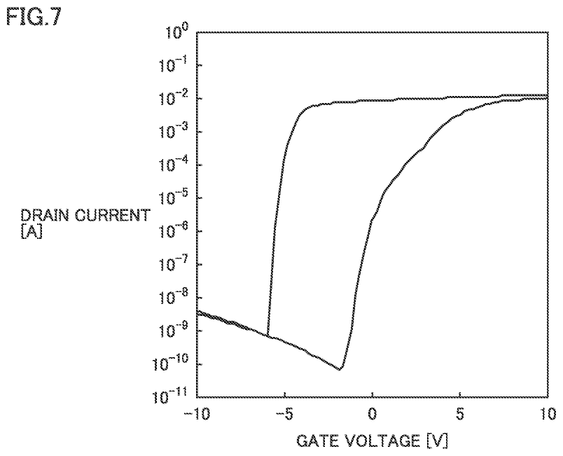

FIG. 7 shows an electrical property of transistor 200 including the ferroelectric film according to the present embodiment. In FIG. 7, a change (transfer property) in drain current when scanning the voltage (gate voltage) applied to gate electrode 20 of transistor 200 is measured using a semiconductor parameter analyzer. In the measurement of the transfer property shown in FIG. 7, a gate voltage VG is scanned within a range of −10 V to +10 V, with a drain voltage fixed to 1 V.

The transfer property of transistor 200 is such that the drain current sharply increases and decreases with polarization inversion of gate insulating film 30 as shown in FIG. 7 and the drain current shows a history with respect to the gate voltage.

As described above, transistor 200 is considered as an example of an electronic component including the ferroelectric film according to the present embodiment, and an electrode formed on a surface of the ferroelectric film. Transistor 200 includes gate electrode 20, source electrode 50 and drain electrode 60, and the ferroelectric film is formed on gate electrode 20 as gate insulating film 30 of a ferroelectric field-effect transistor. This makes it possible to implement transistor 200 that can control the polarization state through the application of the electric field, and to use transistor 200 as a storage element.

It should be understood that the embodiment disclosed herein is illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 substrate; 2 first electrode; 3 dielectric layer; 4 second electrode; 20 gate electrode; 30 gate insulating film; 40 channel forming film; 50 source electrode; 60 drain electrode; 100 capacitor; 200 transistor.

1. A ferroelectric film comprising:
hafnium oxide having a fluorite structure;
a metal oxide having one or more elements selected from La, Ce and Bi; and
less than 5 mol % of carbon,
wherein the ferroelectric film is a polycrystalline body having an average particle size of less than 10 nm.

2. The ferroelectric film according to claim 1, wherein an amount of the metal oxide contained in the ferroelectric film is 1 mol % to 15 mol %.

3. The ferroelectric film according to claim 1, wherein an amount of the carbon in the ferroelectric film is less than 2 mol %.

4. An electronic component comprising:
the ferroelectric film of claim 1; and
an electrode on a surface of the ferroelectric film.

5. The electronic component according to claim 4, wherein
the electrode is a first electrode on a first main surface of the ferroelectric film, and the electronic component further includes a second electrode on a second main surface of the ferroelectric film opposite the first main surface, and the first electrode, the ferroelectric film and the second electrode are arranged to form a capacitor.

6. The electronic component according to claim 4, wherein the ferroelectric film has a thickness of 60 nm.

7. The electronic component according to claim 4, wherein an amount of the metal oxide contained in the ferroelectric film is 1 mol % to 15 mol %.

8. The electronic component according to claim 4, wherein an amount of the carbon in the ferroelectric film is less than 2 mol %.

9. The electronic component according to claim 4, wherein
the electrode is a gate electrode on a first main surface of the ferroelectric film, and the electronic component further includes a source electrode and a drain electrode, and the ferroelectric film, the gate electrode, the source electrode and the drain electrode are arranged to form a field-effect transistor where the ferroelectric film is a gate insulating film of the ferroelectric field-effect transistor.

10. The electronic component according to claim 9, wherein the ferroelectric film has a thickness of 60 nm.

11. The electronic component according to claim 9, further comprising a channel forming film between the ferroelectric film and the source electrode and the drain electrode.

12. The electronic component according to claim 9, wherein an amount of the metal oxide contained in the ferroelectric film is 1 mol % to 15 mol %.

13. The electronic component according to claim 9, wherein an amount of the carbon in the ferroelectric film is less than 2 mol %.
